(19) United States
(12) Patent Application Publication
(10) Pub. No.: US 2025/0105791 A1
(43) Pub. Date: Mar. 27, 2025

(54) MULTI-TRANSMISSION ENVELOPE TRACKING CIRCUIT

(71) Applicant: Qorvo US, Inc., Greensboro, NC (US)

(72) Inventor: Nadim Khlat, Cugnaux (FR)

(21) Appl. No.: 18/832,085

(22) PCT Filed: Jan. 19, 2023
(86) PCT No.: PCT/US2023/060889

§ 371 Date: Jul. 22, 2024

Related U.S. Application Data
(60) Provisional application No. 63/305,897, filed on Feb. 2, 2022.

(51) Int. Cl. H03F 1/02; H03F 3/19; H03F 3/24

(52) U.S. Cl. CPC H03F 1/0227; H03F 1/0288; H03F 3/19; H03F 3/245; H03F 2200/451

(57) ABSTRACT

A multi-transmission envelope tracking (ET) circuit is provided. The multi-transmission ET circuit includes multiple voltage circuits configured to generate multiple modulated voltages for amplifying multiple radio frequency (RF) signals, respectively. Each of the voltage circuits is configured to generate a respective modulated voltage based on a respective supply voltage so generated to prevent amplitude distortion in the respective modulated voltage. In this regard, a control circuit is provided to determine an appropriate supply voltage for each of the voltage amplifiers. In embodiments disclosed herein, the control circuit determines a respective supply voltage for each of the voltage circuits based on a respective peak-to-peak range of the respective modulated voltage. As a result, it is possible to improve operating efficiency of the voltage circuits concurrent to reducing amplitude distortion, energy waste, and heat dissipation.

### RELATED APPLICATIONS

This application claims the benefit of U.S. provisional patent application Ser. No. 63/305,897, filed on Feb. 2, 2022, the disclosure of which is hereby incorporated herein by reference in its entirety.

### FIELD OF THE DISCLOSURE

The technology of the disclosure relates generally to an envelope tracking (ET) power management circuit.

### BACKGROUND

The fifth generation (5G) system has been widely regarded as the next generation wireless communication system beyond the current third generation (3G) and fourth generation (4G) systems. In this regard, a 5G-capable wireless communication device is expected to achieve higher data rates, improved coverage range, enhanced signaling efficiency, and reduced latency.

The 5G-capable wireless communication device typically includes multiple transmitters to simultaneously transmit multiple 5G radio frequency (RF) signals under such schemes as Carrier Aggregation (CA) and Evolved-Universal Terrestrial Radio Access (E-UTRA) New Radio (NR) Dual Connectivity (DC) (ENDC). Since the transmitters typically transmit the 5G RF signals in a millimeter wave spectrum, the RF signals can be more susceptible to propagation attenuation and interference. To help mitigate propagation attenuation and maintain desirable data throughput, the 5G-capable wireless communication device typically employs multiple power amplifiers to amplify the RF signals to desired power levels before transmitting the RF signals from the transmitters. As such, it is desirable to ensure that the power amplifiers can operate with optimal efficiency, especially when the RF signals are transmitted with different peak-to-average ratios (PARs).

### SUMMARY

Embodiments of the disclosure relate to a multi-transmission envelope tracking (ET) circuit. The multi-transmission ET circuit includes multiple voltage circuits configured to generate multiple modulated voltages for amplifying multiple radio frequency (RF) signals, respectively. Each of the voltage circuits is configured to generate a respective modulated voltage based on a respective supply voltage so generated to prevent amplitude distortion in the respective modulated voltage. In this regard, a control circuit is provided to determine an appropriate supply voltage for each of the voltage amplifiers. In embodiments disclosed herein, the control circuit determines a respective supply voltage for each of the voltage circuits based on a respective peak-to-peak range of the respective modulated voltage. As a result, it is possible to improve operating efficiency of the voltage circuits concurrent to reducing amplitude distortion, energy waste, and heat dissipation.

In one aspect, a multi-transmission ET circuit is provided. The multi-transmission ET circuit includes an ET integrated circuit (ETIC). The ETIC includes multiple voltage circuits. Each of the voltage circuits is configured to generate a respective one of multiple modulated voltages for amplifying a respective one of multiple RF signals to be transmitted concurrently in multiple defined time intervals. The ETIC also includes a supply voltage circuit. The supply voltage circuit is configured to generate at least two supply voltages at different voltage levels. The ETIC also includes a control circuit. The control circuit is configured to determine a peak-to-peak range of a selected one of the multiple modulated voltages generated by a selected one of the multiple voltage circuits in each of the multiple defined time intervals. The control circuit is also configured to determine a selected supply voltage among the at least two supply voltages based on the determined peak-to-peak range. The control circuit is also configured to cause the supply voltage circuit to provide the selected supply voltage to the selected one of the multiple voltage circuits.

In another aspect, an ETIC is provided. The ETIC includes multiple voltage circuits. Each of the voltage circuits is configured to generate a respective one of multiple modulated voltages for amplifying a respective one of multiple RF signals to be transmitted concurrently in multiple defined time intervals. The ETIC also includes a supply voltage circuit. The supply voltage circuit is configured to generate at least two supply voltages at different voltage levels. The ETIC also includes a control circuit. The control circuit is configured to determine a peak-to-peak range of a selected one of the multiple modulated voltages generated by a selected one of the multiple voltage circuits in each of the multiple defined time intervals. The control circuit is also configured to determine a selected supply voltage among the at least two supply voltages based on the determined peak-to-peak range. The control circuit is also configured to cause the supply voltage circuit to provide the selected supply voltage to the selected one of the multiple voltage circuits.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A is a schematic diagram of an exemplary conventional power amplifier circuit in which a standard linear power amplifier is configured to amplify a radio frequency (RF) signal based on a modulated voltage;

FIG. 1B provides an exemplary illustration of a peak-to-peak range of the modulated voltage in FIG. 1A;

FIG. 1C provides an exemplary illustration of a load impedance of a transmitter circuit coupled to the standard linear power amplifier in FIG. 1A;

FIG. 1D provides an exemplary illustration of an output power of the RF signal in FIG. 1A as a function of the modulated voltage;

FIG. 2A is a schematic diagram of an exemplary conventional power amplifier circuit in which a standard Doherty power amplifier is configured to amplify an RF signal based on a constant voltage;

FIG. 2B provides an exemplary illustration of a carrier output voltage and a peak output voltage as generated by the standard Doherty power amplifier in FIG. 2A;

FIG. 3A is a schematic diagram of an exemplary hybrid power amplifier circuit configured according to an embodiment of the present disclosure to amplify an RF signal based on an envelope tracking (ET) modulated voltage and a modulate load impedance;

FIG. 3B is a graphic diagram illustrating the ET modulated voltage provided to the hybrid power amplifier circuit in FIG. 3A in comparison to the modulated voltage provided to the standard linear power amplifier in FIG. 1A;

FIG. 4 is a schematic diagram of an exemplary multi-transmission ET circuit incorporating the hybrid power amplifier circuit of FIG. 3A; and

FIG. 5 is a schematic diagram of an exemplary user element wherein the multi-transmission ET circuit of FIG. 4 can be provided.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or 30 “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments of the disclosure relate to a multi-transmission envelope tracking (ET) circuit. The multi-transmission ET circuit includes multiple voltage circuits configured to generate multiple modulated voltages for amplifying multiple radio frequency (RF) signals, respectively. Each of the voltage circuits is configured to generate a respective modulated voltage based on a respective supply voltage so generated to prevent amplitude distortion in the respective modulated voltage. In this regard, a control circuit is provided to determine an appropriate supply voltage for each of the voltage amplifiers. In embodiments disclosed herein, the control circuit determines a respective supply voltage for each of the voltage circuits based on a respective peak-to-peak range of the respective modulated voltage. As a result, it is possible to improve operating efficiency of the voltage circuits concurrent to reducing amplitude distortion, energy waste, and heat dissipation.

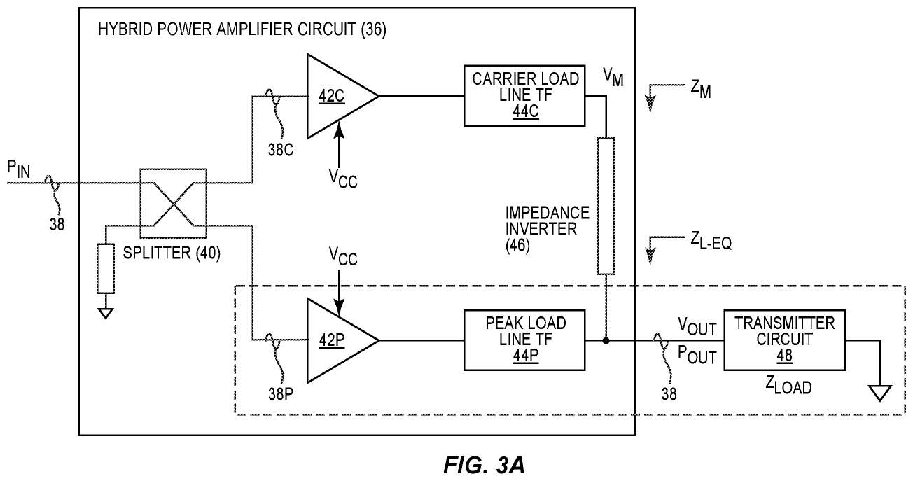

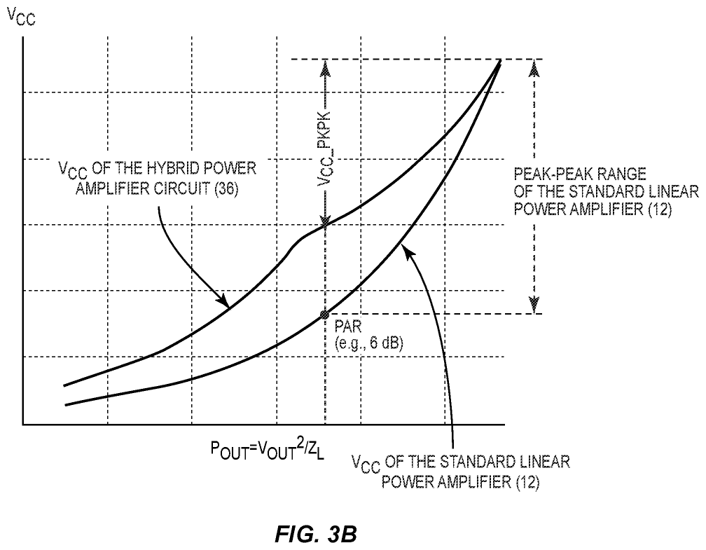

Before discussing the multi-transmission ET circuit according to the present disclosure, starting at FIG. 3A, an overview of some conventional power amplifier circuits is first provided to help understand various factors that may affect operating efficiency of a power amplifier.

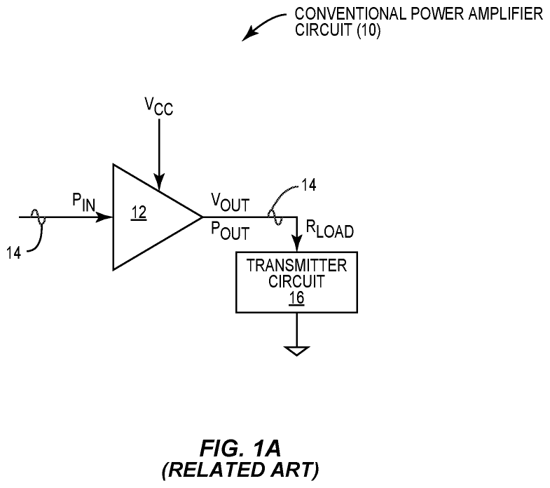

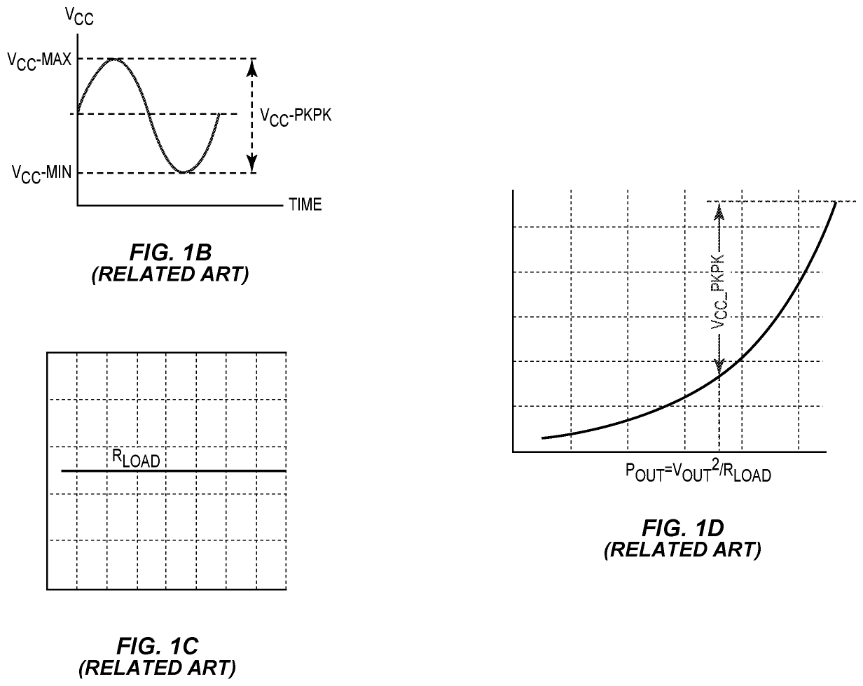

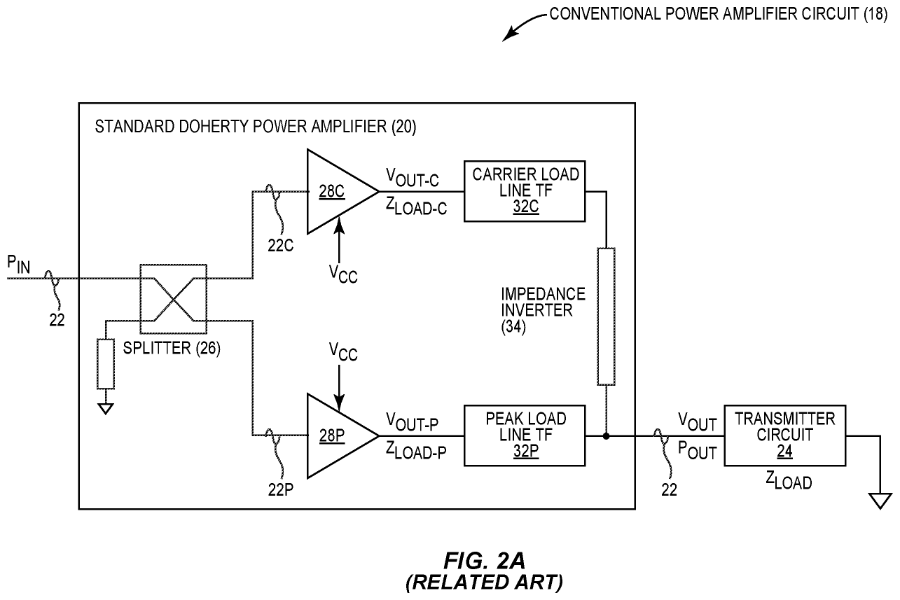

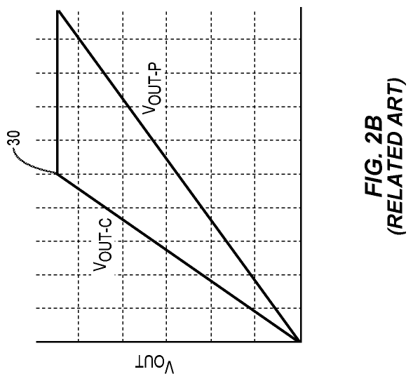

FIG. 1A is a schematic diagram of an exemplary conventional power amplifier circuit 10 in which a standard linear power amplifier 12 is configured to amplify an RF signal 14 based on a modulated voltage V_{CC}. Herein, the standard linear power amplifier 12 is configured to amplify the RF signal 14 from an input power P_{IN} to an output power P_{OUT} based on a modulated voltage V_{CC}. The standard linear power amplifier 12 is coupled to a transmitter circuit 16 configured to transmit the amplified RF signal 14. Accordingly, the output power P_{OUT} of the RF signal 14 can be determined based on the equation (Eq. 1) below.

$${P}_{OUT} = {V}_{OUT}^{2} / {R}_{LOAD} \qquad ( Eq . 1 )$$

In the equation (Eq. 1), V_{OUT} represents an output voltage of the amplified RF signal 14, which is related to the modulated voltage V_{CC} (V_{OUT}=V_{CC}−ΔV). Herein, ΔV represents a voltage drop between two electrodes of an output transistor (not shown) in the standard linear power amplifier 12. Specifically, if the output transistor is a bipolar junction transistor (BJT), the ΔV represents a voltage drop between a collector electrode and an emitter electrode of the BJT. In case the output transistor is a complementary metal-oxide semiconductor (CMOS) transistor, the ΔV represents a voltage drop between the source electrode and the drain electrode of the CMOS transistor. The standard linear power amplifier 12 is said to operate in compression when the modulated voltage V_{CC} is substantially equal to the output voltage V_{OUT}. Under such condition, the ΔV will be substantially close to a saturation voltage of the output transistor and the standard linear power amplifier 12 will render a higher efficiency. R_{LOAD} represents a load impedance of the transmitter circuit 16. Notably, when the standard linear power amplifier 12 operates in compression, equation (Eq. 1) can be re-written as the equation (Eq. 1.1) below.

$${P}_{OUT} \approx {V}_{CC}^{2} / {R}_{LOAD} \qquad ( Eq . 1.1 )$$

FIG. 1B provides an exemplary illustration of a peak-to-peak range V_{CC-PKPK} of the modulated voltage V_{CC} in FIG. 1A. As the modulated voltage V_{CC} varies over time between a maximum modulated voltage V_{CC-MAX} and a minimum modulated voltage V_{CC-MIN}, the peak-to-peak range V_{CC-PKPK} of the modulated voltage V_{CC} can be calculated as V_{CC-PKPK}=V_{CC-MAX}−V_{CC-MIN}.

FIG. 1C provides an exemplary illustration of the load impedance R_{LOAD} of the transmitter circuit 16. For the standard linear power amplifier 12, the load impedance R_{LOAD} is a constant, which implies that the load impedance R_{LOAD} represents a real component of a complex impedance.

Understandably, the input power P_{IN} of the RF signal 14 can be time-variant. As such, the output power P_{OUT} of the RF signal 14 will likewise be time-variant. According to the equation (Eq. 1), since the load impedance R_{LOAD} is constant, the output power P_{OUT} can only become time-variant when the output voltage V_{OUT} is time-variant. Accordingly, based on equation (Eq. 1.1), the modulated voltage V_{CC} must be so generated to be time-variant as well. As such, the output power P_{OUT} can be said to be a function of the modulated voltage V_{CC}.

In this regard, FIG. 1D provides an exemplary illustration of the output power P_{OUT} as a function of the modulated voltage V_{CC}. Given that the output power P_{OUT} is driven by the modulated voltage V_{CC}, the peak-to-peak range V_{CC-PKPK}, as shown in FIG. 1B, will be dictated by peak-to-average ratio (PAR) of the output power P_{OUT}.

FIG. 2A is a schematic diagram of an exemplary conventional power amplifier circuit 18 in which a standard Doherty power amplifier 20 is configured to amplify an RF signal 22 based on a modulated voltage V_{CC}. Herein, the standard Doherty power amplifier 20 is configured to amplify the RF signal 22 from an input power P_{IN} to an output power P_{OUT} based on a constant voltage V_{CC}. The standard Doherty power amplifier 20 is coupled to a transmitter circuit 24 configured to transmit the amplified RF signal 22. Accordingly, the output power P_{OUT} of the RF signal 22 can be determined based on the equation (Eq. 2) below.

$${P}_{OUT} = {V}_{OUT}^{2} / {Z}_{LOAD} \qquad ( Eq . 2 )$$

In the equation (Eq. 2), V_{OUT} represents an output voltage of the amplified RF signal 22. Z_{LOAD} represents a complex load impedance of the transmitter circuit 24.

The standard Doherty power amplifier 20 includes a splitter 26, a carrier amplifier 28C, and a peak amplifier 28P. The splitter 26 splits the RF signal 22 into a pair of signals 22C and 22P that are orthogonal to each other. The carrier amplifier 28C is activated all the time to amplify the signal 22C at any power level. The peak amplifier 28P, on the other hand, is only activated when the carrier amplifier 28C starts to run into compression. When activated, the peak amplifier 28P will provide extra power capability that the carrier amplifier 28C is unable to provide. As a result, the standard Doherty power amplifier 20 can boost the output power P_{OUT} to a higher level, thus making it possible to handle larger peaks in the RF signal 22 without causing amplitude clipping.

Specifically, the carrier amplifier 28C amplifies the signal 22C to a carrier output voltage V_{OUT-C} based on the constant voltage V_{CC}. The peak amplifier 28P, when activated, will amplify the signal 22P to a peak output voltage V_{OUT-P} based on the constant voltage V_{CC}. The amplified signals 22C and 22P are then combined to regenerate the RF signal 22 with the output power P_{OUT}, which is a function of the output voltage V_{OUT} and the complex load impedance Z_{LOAD} according to the equation (Eq. 2).

FIG. 2B provides an exemplary illustration of the carrier output voltage V_{OUT-C} and the peak output voltage V_{OUT-P} as generated by the standard Doherty power amplifier 20 in FIG. 2A. As illustrated, the carrier output voltage V_{OUT-C} increases at a faster rate than the peak output voltage V_{OUT-P}, an indication that the peak amplifier 28P jumps into action later than the carrier amplifier 28C. Notably, the carrier output voltage V_{OUT-C} levels off after a point 30, at which the carrier amplifier 28C runs into compression.

With reference back to FIG. 2A, the standard Doherty power amplifier 20 further includes a carrier load line transfer function circuit 32C, a peak load line transfer function circuit 32P, and an impedance inverter circuit 34, which are configured to cause the complex load impedance Z_{LOAD} to be modulated.

As discussed above, the standard linear power amplifier 12 in FIG. 1A is configured to amplify the RF signal 14 to the time-variant output power P_{OUT} based on the time-variant modulated voltage V_{CC} and a constant real load impedance R_{LOAD}. In contrast, the standard Doherty power amplifier 20 in FIG. 2A is configured to amplify the RF signal 22 to the time-variant output power P_{OUT} based on the constant voltage V_{CC} and a time-variant modulated complex load impedance Z_{LOAD}. Although the standard linear power amplifier 12 and the standard Doherty power amplifier 20 can each amplify a respective one of the RF signal 14 and the RF signal 22 to the respective output power P_{OUT}, a hybrid power amplifier that combines the voltage modulation capability of the standard linear power amplifier 12 and the impedance modulation capability of the standard Doherty power amplifier 20 can provide a distinct advantage over the standard linear power amplifier 12 and the standard Doherty power amplifier 20.

In this regard, FIG. 3A is a schematic diagram of an exemplary hybrid power amplifier circuit 36 configured according to an embodiment of the present disclosure to amplify an RF signal 38 from an input power P_{IN} to an output power P_{OUT} based on an ET modulated voltage V_{CC} and a modulated load impedance Z_{M}. In an embodiment, the hybrid power amplifier circuit 36 includes a splitter 40, a carrier amplifier 42C, a peak amplifier 42P, a carrier load line transfer function circuit 44C, a peak load line transfer function circuit 44P, and an impedance inverter 46. The hybrid power amplifier circuit 36 is coupled to a transmitter circuit 48, which has a complex load impedance Z_{LOAD} and is configured to transmit the amplified RF signal 38.

The hybrid power amplifier circuit 36 is distinctively different from the standard Doherty power amplifier 20 in several aspects.

First, the carrier amplifier 42C and the peak amplifier 42P are each configured to receive the ET modulated voltage V_{CC}, as opposed to the constant voltage V_{CC} received by the carrier amplifier 28C and the peak amplifier 28P in the standard Doherty power amplifier 20. The ET modulated voltage V_{CC} is a time-variant carrier voltage envelope VM associated with the carrier amplifier 42C, which tracks a time-variant modulated voltage so generated to track a time-variant power envelope of the RF signal 38.

Second, in anticipation of an increase in the output power P_{OUT}, the peak amplifier 42P is activated before the carrier amplifier 42C starts to run into compression. By activating the peak amplifier 42P earlier, the modulated load impedance Z_{M} will start to reduce sooner. In an embodiment, the modulated load impedance is inversely related to an equivalent load impedance ZL-EQ, as shown in the equation (Eq. 3) below.

$${Z}_{M} = - {K}_{a}^{2} / {Z}_{L - EQ} \qquad ( Eq . 3 )$$

In the equation (Eq. 3) above, Kₐ represents a coefficient of the impedance inverter 46 and the equivalent load impedance ZL-EQ represents a total impedance of the peak amplifier 42P and the transmitter circuit 48. For a detailed description as to how the hybrid power amplifier circuit 36 can reduce a peak-to-peak range of the ET modulated voltage V_{CC} and operate with improved efficiency as a result of receiving the ET modulated voltage V_{CC} and modulating the load impedance Z_{M}, please refer to U.S. Provisional Patent Application No. 63/305,829, entitled “HYBRID POWER AMPLIFIER CIRCUIT.”

FIG. 3B is a graphic diagram illustrating the ET modulated voltage V_{CC} provided to the hybrid power amplifier circuit 36 in FIG. 3A in comparison to the modulated voltage V_{CC} provided to the standard linear power amplifier 12 in FIG. 1A. As can be seen in FIG. 3B, for a given peak-to-average ratio (PAR) (e.g., 6 dB) of the output power P_{OUT}, the ET modulated voltage V_{CC} of the hybrid power amplifier circuit 36 has a reduced peak-to-peak range V_{CC-PKPK} compared to that of the standard linear power amplifier 12. The reduced peak-to-peak range V_{CC-PKPK} not only can improve operating efficiency of the hybrid power amplifier circuit 36 (particularly the carrier amplifier 42C), but can also help improve operating efficiency of an ET integrated circuit (ETIC) that generates the ET modulated voltage V_{CC}.

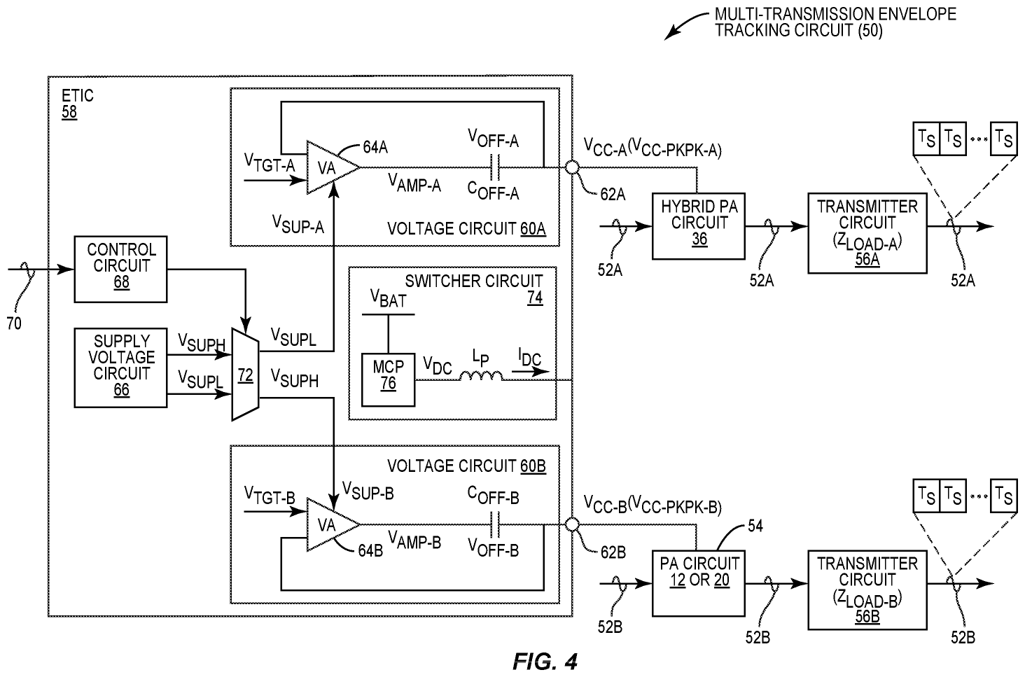

FIG. 4 is a schematic diagram of an exemplary multi-transmission ET circuit 50 that incorporates the hybrid power amplifier circuit 36 in FIG. 3A. The hybrid power amplifier circuit 36 is configured to amplify a first RF signal 52A based on a first modulated voltage V_{CC-A}, which is an ET modulated voltage that tracks power variations of the first RF signal 52A.

The hybrid power amplifier circuit 36 also includes a standard power amplifier circuit 54, which can be the standard linear power amplifier 12 in FIG. 1A or the standard Doherty power amplifier 20 in FIG. 2A. The standard power amplifier circuit 54 is configured to amplify a second RF signal 52B based on a second modulated voltage V_{CC-B}. According to previous discussions, the second modulated voltage V_{CC-B} can be an ET modulated voltage that tracks power variations of the second RF signal 52B when the standard power amplifier circuit 54 is the standard linear power amplifier 12, or an APT modulated voltage that tracks an average power of the second RF signal 52B when the standard power amplifier circuit 54 is the standard Doherty power amplifier 20.

The hybrid power amplifier circuit 36 and the standard power amplifier circuit 54 are coupled to a first transmitter circuit 56A and a second transmitter circuit 56B, respectively. The first transmitter circuit 56A, which presents a first load impedance Z_{LOAD-A}, and the second transmitter circuit 56B, which presents a second load impedance Z_{LOAD-B}, can be configured to transmit the first RF signal 52A and the second RF signal 52B concurrently based on such schemes as Carrier Aggregation (CA) and Evolved-Universal Terrestrial Radio Access (E-UTRA) New Radio (NR) Dual Connectivity (DC) (ENDC). Understandably, the multi-transmission ET circuit 50 can include additional hybrid and/or standard power amplifiers and additional transmitter circuits to concurrently transmit additional RF signals under such schemes as multiple-input multiple-output (MIMO) and massive MIMO (M-MIMO).

In embodiments discussed herein, the first transmitter circuit 56A and the second transmitter circuit 56B are each configured to transmit a respective one of the first RF signal 52A and the second RF signal 52B in multiple defined time intervals T_{S}. In the context of the present disclosure, the defined time intervals T_{S} may refer to the duration of an orthogonal frequency division multiplexing (OFDM) symbol, the duration of a time-division duplex (TDD) slot, or the duration of a TDD mini slot.

The multi-transmission ET circuit 50 includes an ETIC 58, which is configured to generate the first modulated voltage V_{CC-A} and the second modulated voltage V_{CC-B}. The ETIC 58 includes a first voltage circuit 60A and a second voltage circuit 60B that are coupled to the hybrid power amplifier circuit 36 and the standard power amplifier circuit 54 via a first voltage output 62A and a second voltage output 62B, respectively. The first voltage circuit 60A is configured to generate the first modulated voltage V_{CC-A} based on a first target voltage V_{TGT-A} and a first supply voltage V_{SUP-A}. The second voltage circuit 60B is configured to generate the second modulated voltage V_{CC-B} based on a second target voltage V_{TGT-B} and a second supply voltage V_{SUP-B}.

The first target voltage V_{TGT-A} and the second target voltage V_{TGT-B} may be generated by a transceiver circuit (not shown) that also generates the first RF signal 52A and the second RF signal 52B. In this regard, the first target voltage V_{TGT-A} can indicate power variation of the first RF signal 52A in each of the defined time intervals T_{S}. Similarly, the second target voltage V_{TGT-B} can indicate power variation or average power of the second RF signal 52B in each of the defined time intervals T_{S}. Accordingly, the first voltage circuit 60A can generate the first modulated voltage V_{CC-A} that tracks the power variation of the first RF signal 52A. Likewise, the second voltage circuit 60B can generate the second modulated voltage V_{CC-B} that tracks the power variation or the average power of the second RF signal 52B.

In an embodiment, the first voltage circuit 60A includes a first voltage amplifier 64A coupled in series with a first offset capacitor C_{OFF-A}. The first voltage amplifier 64A is configured to generate a first initial modulated voltage V_{AMP-A} based on the first target voltage V_{TGT-A} and the first supply voltage V_{SUP-A}. The first offset capacitor C_{OFF-A} is coupled between the first voltage amplifier 64A and the first voltage output 62A. The first offset capacitor C_{OFF-A} is configured to raise the first initial modulated voltage V_{AMP-A} by a first offset voltage V_{OFF-A} to generate the first modulated voltage V_{CC-A} (V_{CC-A}=V_{AMP-A}+V_{OFF-A}). The first initial modulated voltage V_{AMP-A}, which may be determined by the transceiver circuit in each of the defined time intervals T_{S}, can be determined based on the equation (Eq. 3).

$${V}_{AMP - A} = {V}_{CC - AMAX} - {V}_{CC - AMIN} + {V}_{HEAD - A} \qquad ( Eq . 4 )$$

In the equation (Eq. 3), V_{CC-AMAX} and V_{CC-A} MIN represent a peak and a bottom of the first modulated voltage V_{CC-A}, respectively. V_{HEAD-A} represents a headroom voltage that is typically a constant voltage.

The second voltage circuit 60B includes a second voltage amplifier 64B coupled in series with a second offset capacitor C_{OFF-B}. The second voltage amplifier 64B is configured to generate a second initial modulated voltage V_{AMP-B} based on the second target voltage V_{TGT-B} and the second supply voltage V_{SUP-B}. The second offset capacitor C_{OFF-B} is coupled between the second voltage amplifier 64B and the second voltage output 62B. The second offset capacitor C_{OFF-B} is configured to raise the second initial modulated voltage V_{AMP-B} by a second offset voltage V_{OFF-B} to generate the second modulated voltage V_{CC-B} (V_{CC-B}=V_{AMP-B}+V_{OFF-B}). The second initial modulated voltage V_{AMP-B}, which may be determined by the transceiver circuit in each of the defined time intervals T_{S}, can be determined based on the equation (Eq. 4).

$${V}_{AMP - B} = {V}_{CC - BMAX} - {V}_{CC - BMIN} + {V}_{HEAD - B} \qquad ( Eq . 4 )$$

In the equation (Eq. 4), V_{CC-BMAX} and V_{CC-BMIN} represent a peak and a bottom of the second modulated voltage V_{CC-B}, respectively. V_{HEAD-B} represents a headroom voltage that is typically a constant voltage.

The ETIC 58 includes a supply voltage circuit 66, which is configured to generate multiple supply voltages V_{SUPH}, V_{SUPL} at different voltage levels (V_{SUPH}>V_{SUPL}). In an embodiment, the supply voltages V_{SUPH}, V_{SUPL} can be determined based on the equations (Eq. 5 and Eq. 6) below. For specific examples as to how the supply voltage circuit 64 generates the supply voltages V_{SUPH}, V_{SUPL}, please refer to U.S. Pat. No. 10,903,796 B2, entitled “VOLTAGE GENERATION CIRCUIT AND RELATED ENVELOPE TRACKING AMPLIFIER APPARATUS.”

$${V}_{SUPH} = Max ( {V}_{AMP - A} , {V}_{AMP - B} ) \qquad ( Eq . 5 )$$

$${V}_{SUPL} = \frac{{V}_{SUPH}}{Floor [ \frac{{V}_{SUPH}}{Min ( {V}_{AMP - A} , {V}_{AMP - B} )} ]} \qquad ( Eq . 6 )$$

The ETIC 58 also includes a control circuit 68, which can be a field-programmable gate array (FPGA), as an example. In an embodiment, the control circuit 68 may receive an advance-indication signal 70 (e.g., from the transceiver circuit) that indicates peak-to-peak ranges of the first RF signal 52A and the second RF signal 52B in an upcoming one of the defined time intervals T_{S}. In an embodiment, the ETIC 58 may include an output circuit 72 coupled to the supply voltage circuit 66. The output circuit 72 is configured to receive both the supply voltages V_{SUPH}, V_{SUPL} from the supply voltage circuit 66 and selectively output any of the supply voltages V_{SUPH}, V_{SUPL} to any of the first voltage circuit 60A and the second voltage circuit 60B. Accordingly, the control circuit 68 may control the output circuit 72 to provide an appropriate one of the supply voltages V_{SUPH}, V_{SUPL} to each of the first voltage circuit 60A and the second voltage circuit 60B.

In a non-limiting example, the first RF signal 52A has a first peak power and the second RF signal 52B has a second peak power that is higher than the first peak power. In this regard, the second modulated voltage V_{CC-B} needs to be higher than the first modulated voltage V_{CC-A} to prevent amplitude distortion in the second RF signal 52B. Accordingly, the supply voltage circuit 66 will generate the higher supply voltage V_{SUPH} in accordance with the peak-to-peak range of the second modulated voltage V_{CC-B} and the control circuit 68 will control the output circuit 72 to provide the higher supply voltage V_{SUPH} to the second voltage amplifier 64B as the second supply voltage V_{SUP-B}.

Generally speaking, a voltage amplifier will operate with higher efficiency based on the lower supply voltage V_{SUPL}, particularly for the first voltage amplifier 64A. Nevertheless, the lower supply voltage V_{SUPL} must not be too low to cause amplitude distortion in the first modulated voltage V_{CC-A}. Notably, since the hybrid power amplifier circuit 36 can effectively operate with a lower peak-to-peak range, there is a possibility for the first voltage amplifier 64A to operate efficiently based on the lower supply voltage V_{SUPL}. As such, the control circuit 68 may control the output circuit 72 to provide the lower supply voltage V_{SUPL} to the first voltage amplifier 64A as the first supply voltage V_{SUP-A}. As a result, both the first voltage amplifier 64A and the hybrid power amplifier circuit 36 can operate with improved efficiency.

In an example, assume that V_{CC-AMAX}=V_{CC-BMAX}=5.5 V, V_{CC-A} MIN=3.0 V, V_{CC-BMIN}=1.0 V, and V_{HEAD-A}=V_{HEAD-B}=0.5 V. Accordingly, the first modulated voltage V_{CC-A} has a peak-to-peak range of 2.5 V, and the second modulated voltage V_{CC-B} has a peak-to-peak range of 4.5 V. Thus, the higher supply voltage V_{SUPH} will be 5.0 V according to equation (Eq. 5), and the lower supply voltage V_{SUPL} will approximately be 3.33 V according to equation (Eq. 6). In this regard, the lower supply voltage V_{SUPL} will be high enough for the peak-to-peak range (2.5 V) of the first modulated voltage V_{CC-A} to thereby avoid amplitude distortion in the first RF signal 52A.

The ETIC 58 further includes a switcher circuit 74, which includes a multi-level charge pump (MCP) 76 and a power inductor L_{P}. The MCP 76, which can be a direct-current (DC)-DC buck-booster converter, as an example, is configured to generate a DC voltage V_{DC} as a function of a battery voltage V_{BAT}. In an embodiment, the DC voltage V_{DC} may be equal to 0×V_{BAT}, 1×V_{BAT}, or 2×V_{BAT}. The power inductor L_{P} is configured to induce a DC current I_{DC} based on the DC voltage V_{DC}. In an embodiment, the DC current I_{DC} can serve two purposes. First, the DC current I_{DC} provides a DC component to the hybrid power amplifier circuit 36 and the standard power amplifier circuit 54 for amplifying the first RF signal 52A and the second RF signal 52B, respectively. Second, the DC current I_{DC} can be used to modulate the first offset voltage V_{OFF-A} and the second offset voltage V_{OFF-B}.

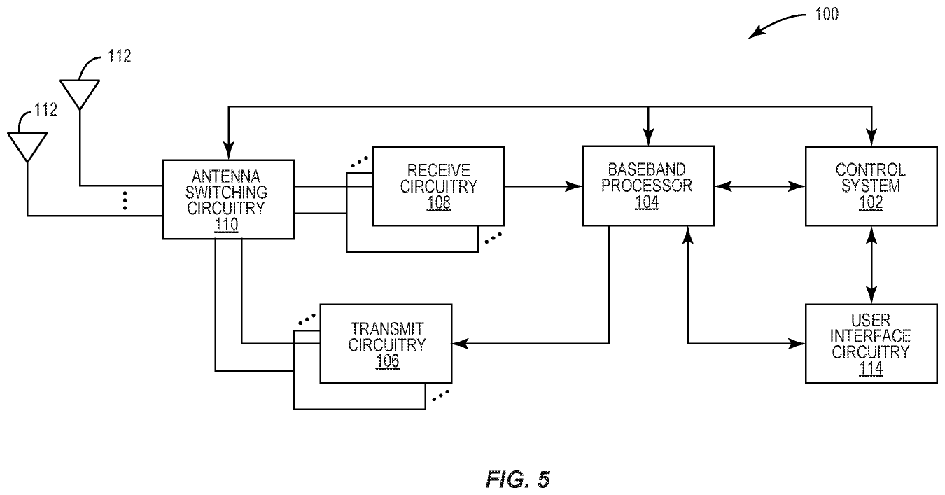

The multi-transmission ET circuit 50 of FIG. 4 can be provided in a user element to enable memory distortion neutralization according to embodiments described above. In this regard, FIG. 5 is a schematic diagram of an exemplary user element 100 wherein the multi-transmission ET circuit 50 of FIG. 4 can be provided.

Herein, the user element 100 can be any type of user elements, such as mobile terminals, smart watches, tablets, computers, navigation devices, access points, and like wireless communication devices that support wireless communications, such as cellular, wireless local area network (WLAN), Bluetooth, and near field communications. The user element 100 will generally include a control system 102, a baseband processor 104, transmit circuitry 106, receive circuitry 108, antenna switching circuitry 110, multiple antennas 112, and user interface circuitry 114. In a non-limiting example, the control system 102 can be a field-programmable gate array (FPGA), as an example. In this regard, the control system 102 can include at least a microprocessor(s), an embedded memory circuit(s), and a communication bus interface(s). The receive circuitry 108 receives radio frequency signals via the antennas 112 and through the antenna switching circuitry 110 from one or more base stations. A low noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams using analog-to-digital converter(s) (ADC).

The baseband processor 104 processes the digitized received signal to extract the information or data bits conveyed in the received signal. This processing typically comprises demodulation, decoding, and error correction operations, as will be discussed in greater detail below. The baseband processor 104 is generally implemented in one or more digital signal processors (DSPs) and application specific integrated circuits (ASICs).

For transmission, the baseband processor 104 receives digitized data, which may represent voice, data, or control information, from the control system 102, which it encodes for transmission. The encoded data is output to the transmit circuitry 106, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission, and deliver the modulated carrier signal to the antennas 112 through the antenna switching circuitry 110. The multiple antennas 112 and the replicated transmit and receive circuitries 106, 108 may provide spatial diversity. Modulation and processing details will be understood by those skilled in the art.

Those skilled in the art will recognize improvements and modifications to the preferred embodiments of the present disclosure. All such improvements and modifications are considered within the scope of the concepts disclosed herein and the claims that follow.

1. A multi-transmission envelope tracking (ET) circuit comprising:
an ET integrated circuit (ETIC) comprising:
a plurality of voltage circuits each configured to generate a respective one of a plurality of modulated voltages for amplifying a respective one of a plurality of radio frequency, RF, signals to be transmitted concurrently in a plurality of defined time intervals;
a supply voltage circuit configured to generate at least two supply voltages at different voltage levels; and
a control circuit configured to:
receive an indication signal indicating respective peak-to-peak ranges of the plurality of RF signals;
determine a peak-to-peak range of a selected one of the plurality of modulated voltages generated by a selected one of the plurality of voltage circuits in each of the plurality of defined time intervals based on the received indication signal;
determine a selected supply voltage among the at least two supply voltages based on the determined peak-to-peak range; and
cause the supply voltage circuit to provide the selected supply voltage to the selected one of the plurality of voltage circuits.

2. The multi-transmission ET circuit of claim 1, wherein:
a first voltage circuit among the plurality of voltage circuits is configured to generate a first modulated voltage among the plurality of modulated voltages for amplifying a first one of the plurality of RF signals having a first peak power in each of the plurality of defined time intervals; and
a second voltage circuit among the plurality of voltage circuits is configured to generate a second modulated voltage among the plurality of modulated voltages for amplifying a second one of the plurality of RF signals having a second peak power higher than the first peak power in each of the plurality of defined time intervals.

3. The multi-transmission ET circuit of claim 2, wherein the control circuit is further configured to:
determine the peak-to-peak range of the first modulated voltage in each of the plurality of defined time intervals;
determine, based on the determined peak-to-peak range, that the first voltage circuit can generate the first modulated voltage based on a lower one of the at least two supply voltages; and
cause the supply voltage circuit to provide the lower one of the at least two supply voltages to the first voltage circuit.

4. The multi-transmission ET circuit of claim 3, further comprising:
a hybrid power amplifier circuit coupled to the first voltage circuit and configured to amplify the first one of the plurality of RF signals in each of the plurality of defined time intervals based on the first modulated voltage; and
a first transmitter circuit coupled to the hybrid power amplifier circuit and configured to transmit the first one of the plurality of RF signals.

5. The multi-transmission ET circuit of claim 4, wherein the hybrid power amplifier circuit is further configured to modulate a load impedance of the first transmitter circuit such that the hybrid power amplifier circuit can achieve a determined power amplifier efficiency in each of the plurality of defined time intervals based on the peak-to-peak range of the first modulated voltage.

6. The multi-transmission ET circuit of claim 2, wherein the control circuit is further configured to:
determine the peak-to-peak range of the second one of the plurality of RF signals in the each of the plurality of defined time intervals;
determine, based on the determined peak-to-peak range, that the second voltage circuit can generate the second modulated voltage based on a higher one of the at least two supply voltages; and
cause the supply voltage circuit to provide the higher one of the at least two supply voltages to the second voltage circuit.

7. The multi-transmission ET circuit of claim 6, further comprising:
a standard power amplifier circuit coupled to the second voltage circuit and configured to amplify the second one of the plurality of RF signals in each of the plurality of defined time intervals based on the second modulated voltage; and
a second transmitter circuit coupled to the standard power amplifier circuit and configured to transmit the second one of the plurality of RF signals.

8. The multi-transmission ET circuit of claim 7, wherein the standard power amplifier circuit comprises one of a standard linear power amplifier and a standard Doherty power amplifier.

9. The multi-transmission ET circuit of claim 2, wherein:
the first voltage circuit comprises:
a first voltage amplifier configured to generate a first initial modulated voltage based on the first target voltage; and
a first offset capacitor configured to raise the first initial modulated voltage by a first offset voltage to generate the first modulated voltage; and
the second voltage circuit comprises:
a second voltage amplifier configured to generate a second initial modulated voltage based on the second target voltage; and
a second offset capacitor configured to raise the second initial modulated voltage by a second offset voltage to generate the second modulated voltage.

10. The multi-transmission ET circuit of claim 9, wherein the ETIC further comprises a switcher circuit, the switcher circuit comprising:
a multi-level charge pump (MCP) configured to generate a direct-current (DC) voltage as a function of a battery voltage; and
a power inductor configured to induce a DC current based on the DC voltage to thereby modulate the first offset voltage and the second offset voltage.

11. An envelope tracking (ET) integrated circuit (ETIC), comprising:
a plurality of voltage circuits each configured to generate a respective one of a plurality of modulated voltages for amplifying a respective one of a plurality of radio frequency (RF) signals to be transmitted concurrently in a plurality of defined time intervals;
a supply voltage circuit configured to generate at least two supply voltages at different voltage levels; and
a control circuit configured to:
receive an indication signal indicating respective peak-to-peak ranges of the plurality of RF signals;
determine a peak-to-peak range of a selected one of the plurality of modulated voltages generated by a selected one of the plurality of voltage circuits in each of the plurality of defined time intervals based on the received indication signal;
determine a selected supply voltage among the at least two supply voltages based on the determined peak-to-peak range; and
cause the supply voltage circuit to provide the selected supply voltage to the selected one of the plurality of voltage circuits.

12. The ETIC of claim 11, wherein:
a first voltage circuit among the plurality of voltage circuits is configured to generate a first modulated voltage among the plurality of modulated voltages for amplifying a first one of the plurality of RF signals having a first peak power in each of the plurality of defined time intervals; and
a second voltage circuit among the plurality of voltage circuits is configured to generate a second modulated voltage among the plurality of modulated voltages for amplifying a second one of the plurality of RF signals having a second peak power higher than the first peak power in each of the plurality of defined time intervals.

13. The ETIC of claim 12, wherein the control circuit is further configured to:
determine the peak-to-peak range of the first modulated voltage in each of the plurality of defined time intervals;
determine, based on the determined peak-to-peak range, that the first voltage circuit can generate the first modulated voltage based on a lower one of the at least two supply voltages; and
cause the supply voltage circuit to provide the lower one of the at least two supply voltages to the first voltage circuit.

14. The ETIC of claim 13, wherein:
a hybrid power amplifier circuit is coupled to the first voltage circuit and configured to amplify the first one of the plurality of RF signals in each of the plurality of defined time intervals based on the first modulated voltage; and
a first transmitter circuit is coupled to the hybrid power amplifier circuit and configured to transmit the first one of the plurality of RF signals.

15. The ETIC of claim 14, wherein the hybrid power amplifier circuit is further configured to modulate a load impedance of the first transmitter circuit such that the hybrid power amplifier circuit can achieve a determined power amplifier efficiency in each of the plurality of defined time intervals based on the peak-to-peak range of the first modulated voltage.

16. The ETIC of claim 12, wherein the control circuit is further configured to:
determine the peak-to-peak range of the second one of the plurality of RF signals in the each of the plurality of defined time intervals;
determine, based on the determined peak-to-peak range, that the second voltage circuit can generate the second modulated voltage based on a higher one of the at least two supply voltages; and
cause the supply voltage circuit to provide the higher one of the at least two supply voltages to the second voltage circuit.

17. The ETIC of claim 16, wherein:
a standard power amplifier circuit is coupled to the second voltage circuit and configured to amplify the second one of the plurality of RF signals in each of the plurality of defined time intervals based on the second modulated voltage; and
a second transmitter circuit is coupled to the standard power amplifier circuit and configured to transmit the second one of the plurality of RF signals.

18. The ETIC of claim 17, wherein the standard power amplifier circuit comprises one of a standard linear power amplifier and a standard Doherty power amplifier.

19. The ETIC of claim 12, wherein:
the first voltage circuit comprises:
a first voltage amplifier configured to generate a first initial modulated voltage based on the first target voltage; and
a first offset capacitor configured to raise the first initial modulated voltage by a first offset voltage to generate the first modulated voltage; and
the second voltage circuit comprises:
a second voltage amplifier configured to generate a second initial modulated voltage based on the second target voltage; and
a second offset capacitor configured to raise the second initial modulated voltage by a second offset voltage to generate the second modulated voltage.

20. The ETIC of claim 19, further comprising a switcher circuit that comprises:
a multi-level charge pump (MCP) configured to generate a direct-current (DC) voltage as a function of a battery voltage; and
a power inductor configured to induce a DC current based on the DC voltage to thereby modulate the first offset voltage and the second offset voltage.
